(19) United States
(12) Patent Application Publication
(10) Pub. No.: US 2012/0199176 A1
(43) Pub. Date: Aug. 9, 2012

(54) SOLAR CELL MODULE AND METHOD FOR MANUFACTURING THE SAME

(75) Inventors: Seeun Hong, Changwon-si (KR); Chaeyong Lee, Changwon-si (KR); Youngsik Lee, Changwon-si (KR); Jemin Yu, Changwon-si (KR); Hyeyoung Yang, Changwon-si (KR); Sanghwan Park, Changwon-si (KR); Kyungchan Kang, Changwon-si (KR)

(73) Assignee: LG ELECTRONICS INC., Seoul (KR)

(21) Appl. No.: 13/361,387

(22) Filed: Jan. 30, 2012

(30) Foreign Application Priority Data
Feb. 9, 2011 (KR) 10-2011-0011577

(51) Int. Cl. H01L 31/052; H01L 31/18; H01L 31/042

(52) U.S. Cl. 136/246; 136/244; 438/66; 257/E31.001

(57) ABSTRACT

A solar cell module includes a solar cell string including at least two solar cells for generating electricity from sun light; a first sealing member and a second sealing member for sealing a front surface and a rear surface of the solar cell string, respectively; a front glass positioned on the first sealing member for protecting the front surface of the solar cell module; and a back sheet positioned on the second sealing member for protecting the rear surface of the solar cell module. Here, the back sheet includes an outer surface being an even surface including at least one of a plurality of dented portions and a plurality of protruded portions.

### CROSS-REFERENCE TO RELATED APPLICATION

This application claims the priority benefit of Korean Patent Application No. 10-2011-0011557, filed on Feb. 9, 2011 in the Korean Intellectual Property Office, the disclosure of which is incorporated herein by reference.

### BACKGROUND

1. Field of the Disclosure

The present disclosure relates to a solar cell module, and more particularly, to a solar cell having an enhanced heat-dissipating property and a method for manufacturing the same.

2. Description of the Related Art

Recently, as it is expected that conventional energy resource such as petroleum and coal will be exhausted, interest in alternative energy replacing the conventional energy resources is gradually increasing. Among them, a solar cell is spotlighted as a new generation cell using a semiconductor device for directly converting solar energy into electric energy. However, a solar cell has problems in manufacturing cost, conversion efficiency, and lifespan. Therefore, recent studies regarding a solar cell focus on techniques for improving the efficiency of the solar cell.

In a solar cell module, solar cells for generating electricity from the sun light are connected to each other in series or in parallel, and ribbons are connected to front and rear electrodes of the solar cells. In the solar cell module, the heat generated during an operation of the solar cell and the temperature increase by the heat are the biggest factors for decreasing the conversion efficiency of the solar cell module. Accordingly, the problem by the heat is needed to be resolved in order to improve the conversion efficiency the solar cell module.

### SUMMARY

The present disclosure directed to a solar cell module having an enhanced efficiency by suppressing temperature increase through effective heat-dissipating and a method for manufacturing the same.

A solar cell module according to an embodiment of the present invention includes: a solar cell string including at least two solar cells for generating electricity from sun light; a first sealing member and a second sealing member for sealing a front surface and a rear surface of the solar cell string, respectively; a front glass positioned on the first sealing member for protecting the front surface of the solar cell module; and a back sheet positioned on the second sealing member for protecting the rear surface of the solar cell module. Here, the back sheet includes an outer surface being an even surface including at least one of a plurality of dented portions and a plurality of protruded portions.

Also, a method for manufacturing a solar cell module according to another embodiment of the present invention includes: forming a solar cell string by connecting at least two solar cells for generating electricity from sun light; forming a first sealing member and a second sealing member on a front surface and a rear surface of the solar cell string, respectively; mounting a front glass on the first sealing member for protecting the front surface of the solar cell module; and mounting a back sheet on the second sealing member for protecting the rear surface of the solar cell module. The back sheet includes an outer surface being a uneven surface including at least one of a plurality of dented portions and a plurality of protruded portions.

### BRIEF DESCRIPTION OF THE DRAWINGS

FIG. 1 is an exploded perspective view illustrating a solar cell module according to an embodiment of the present invention.

FIG. 2 is an exploded perspective view illustrating a solar cell module according to another embodiment of the present invention.

FIG. 3 is a schematically cross-sectional view illustrating a solar cell according to embodiments of the present invention.

FIG. 4 is a cross-sectional view illustrating a solar cell module including a heat-dissipating layer formed on a back sheet, according to an embodiment of the present invention.

FIG. 5 is a flowchart illustrating a method for manufacturing a solar cell module shown in FIG. 4.

FIG. 6 is a cross-sectional view illustrating a solar cell module including a back sheet having a plurality of dented-protruded portions, according to another embodiment of the present invention.

FIG. 7 is a flowchart illustrating a method for manufacturing a solar cell module shown in FIG. 6.

FIG. 8 is a cross-sectional view illustrating a solar cell module including a back sheet having a plurality of dented-protruded portions and a heat-dissipating layer formed on the uneven surface of the back sheet, according to another embodiment of the present invention.

FIG. 9 is a flowchart illustrating a method for manufacturing a solar cell module shown in FIG. 8.

### DETAILED DESCRIPTION OF THE PREFERRED EMBODIMENTS

Hereinafter, embodiments of the present invention will be described with reference to the accompanying drawings.

In the following description, it will be understood that, when a layer or a film is referred to as being “on” another layer or substrate, it can be directly on the other layer or substrate, or intervening layers may also be present. On the contrary, it will be understood that, when a layer or a film is referred to as being “directly on” another layer or substrate, there is no another layer or film between two elements. Also, it will be understood that, when one portion is “entirely” formed on another portion, the one portion can be formed on a whole portion of the another portion except for some portions (for example, a periphery).

In the figures, the dimensions of layers and regions are exaggerated or schematically illustrated, or some layers are omitted for clarity of illustration. In addition, the dimension of each part as drawn may not reflect an actual size. Further, the same reference numerals are used for the elements that can be classified to the same elements.

Hereinafter, embodiments of the present invention will be described in more detail with reference to the accompanying drawings.

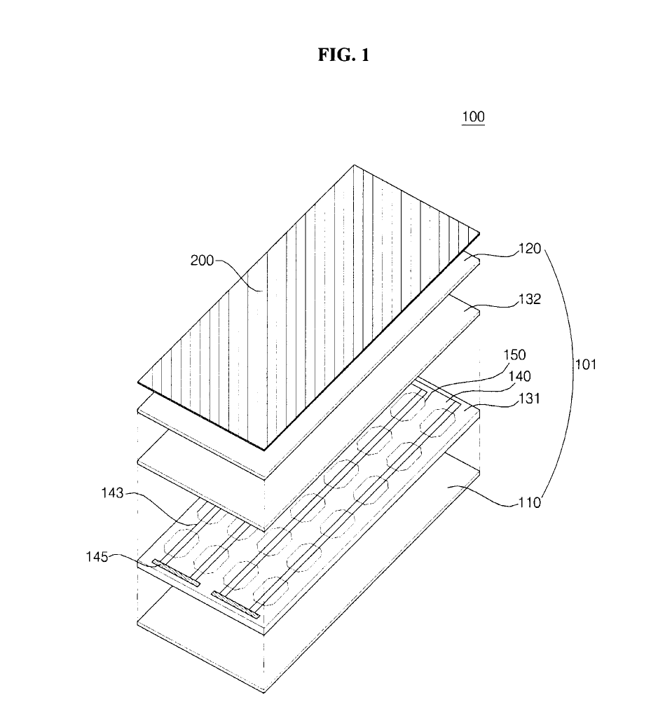

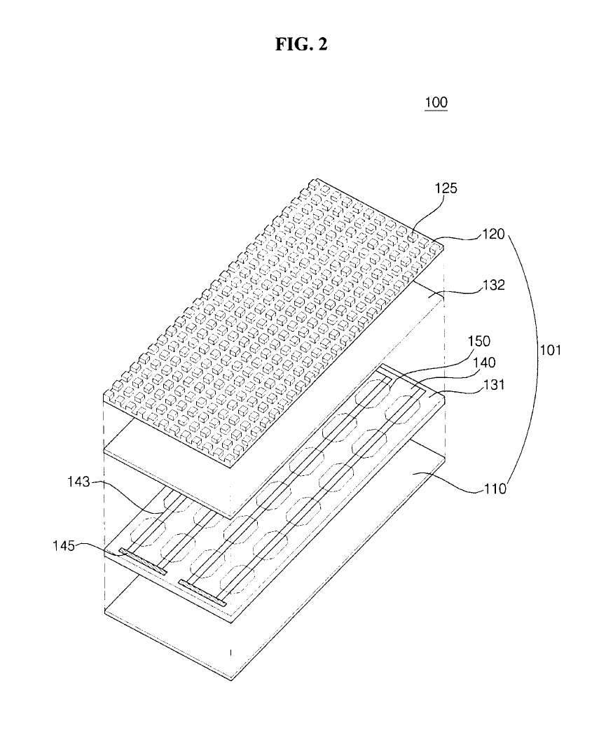

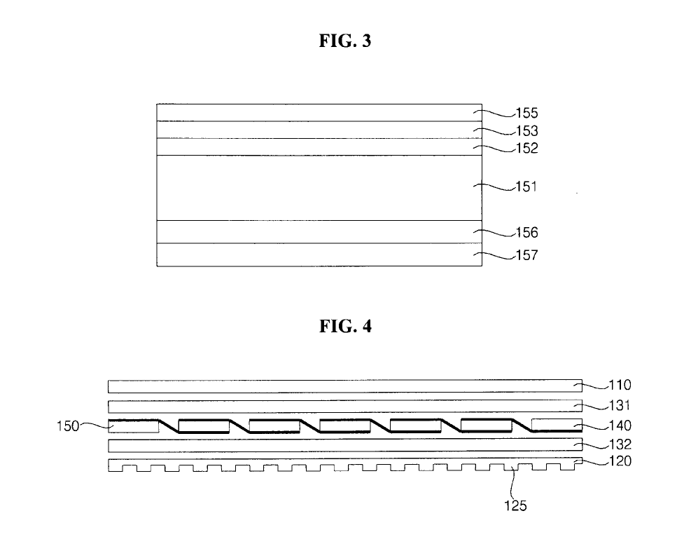

FIG. 1 is an exploded perspective view of a solar cell module according to an embodiment of the present invention, and FIG. 2 is an exploded perspective view of a solar cell module according to another embodiment of the present invention. Also, FIG. 3 is a schematically cross-sectional view of a solar cell applicable to the solar cell modules according to embodiments of the present invention.

Referring to FIGS. 1 and 2, a solar cell module 100 includes a plurality of solar cells 150, a plurality of ribbons 143 for connecting the solar cells 150, a plurality of bus ribbons 145 connecting the ribbons 143, a first sealing member 131 and the second sealing member 132a for sealing both surfaces of the solar cell 150, and a front glass 110 and a back sheet 120 for protecting a light-incident surface and a rear surface of the solar cells 150, respectively.

The back sheet 120 may have a material having high reflexibility in order to reflect and reuse the sun light incident through the front glass 110. However, the present embodiments are not limited thereto. Thus, the back sheet 120 may have a transparent material that the sun light can be incident. In addition, the back sheet 120 may perform water-proof, insulation, and blocking ultraviolet rays, and may have a TPT Tedlar/PET/Tedlar type. However, the present embodiments are not limited thereto. In FIG. 1, the back sheet 120 has a rectangular shape. However, the present embodiments are not limited thereto. Thus, the back sheet 120 may have various shapes (such as, a circular shape, a semicircular shape, and so on), considering the environments of the solar cell module 100.

Referring to FIG. 1, a heat-dissipating layer 200 may be further formed on the back sheet 120. The heat-dissipating layer 200 has a thermal conductivity larger than that of the back sheet 120. The heat-dissipating layer 200 is formed on an outer surface of the back sheet 120 by spraying or coating a heat-dissipating material. Here, the outer surface of the back sheet 120 is a surface opposite to a surface where the second sealing member 132 is attached, and is exposed to the outside.

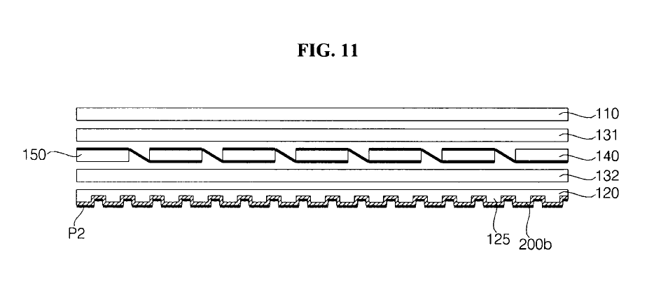

Referring to FIG. 2, the outer surface of the back sheet 120 is a uneven surface. In FIG. 2, the uneven surface includes a plurality of protruded portions 125 as an example. However, the present embodiments are not limited thereto. Thus, the uneven surface may include a plurality of dented portions, or a plurality of dented and protruded portions. The entire outer surface of the back sheet 120 may be the uneven surface 125, or only a portion of outer surface of the back sheet 120 may be the uneven surface 125. Also, as shown in FIG. 8, a heat-dissipating layer 200 may be further formed on the back sheet 120. In this case, the heat-dissipating layer 200 has dented and/or protruded portions corresponding to the dented and/or protruded portions of the back sheet 120.

The back sheet 120 may include at least two layers, and the dented and/or protrude portions may be formed only at an outermost layer. When the back sheet 120 includes at least three layers, the dented and/or protruded portions may be formed at the outermost layer and an intermediate layer. When the dented and/or protrude portions are formed at the intermediate layer as well as the outermost layer, a surface area of the back sheet 120 increases, and thus, the heat can be effectively dissipated through the back sheet 120. In addition, the dented and/or protrude portions may be formed at a surface being in direct contact with the second sealing member 132. In this case, the rear flexibility can increase.

The heat-dissipating layer 200 of FIG. 1 or the dented and/or protruded portions of FIG. 2 enhance the thermal conductivity of the solar cell module 100, and thus, the temperature increase of the solar cell module 100 can be suppressed.

When the heat-dissipating layer 200 is formed by coating the heat-dissipating material on the back sheet 120, the temperature of the operating solar cell module 100 can decrease, and electric power output of the solar cell module 100 per hour can increase. The power generated by the solar cell module 100 including the heat-dissipating layer 200 is more than that of the solar cell module that the heat-dissipating layer 200 is not formed, by 1.08˜1.1%.

Also, the temperature results measured by an infrared camera after the same operation time are as follow. A portion where the heat-dissipating material was coated with a thickness of about 0.5˜1 mm had a maximum temperature of 27.8° C., and another portion where the heat-dissipating material was coated with a thickness of about 0.1˜0.4 mm had a maximum temperature of 31.1° C. The other portion where the heat-dissipating material was not coated had a maximum temperature of 38.8° C. For reference, in the above, the heat-dissipating material was sprayed by a spraying method.

The second sealing member 132 with a size same as that of the back sheet 120 may be formed on the back sheet 120. The plurality of solar cells 150 are arranged to form a plurality of raws on the second sealing member 132.

The first sealing member 131 is formed on the front surface of the solar cell 150, that is, the light-incident surface of the solar cell 150. The first sealing member 131 may be attached on the second sealing member 132 by a lamination method.

Here, the first sealing member 131 and the second sealing member 132 chemically combine respective elements of the solar cells 150. The first sealing member 131 and the second sealing member 132 may include a sealing film of ethylene-vinyl acetate copolymer resin (EVA) having excellent transparency, cushioning property, elastic property, and tensile strength.

On the other hand, the front substrate 110 is positioned on the first sealing member 131 to allow sun light to pass and is preferably a tempered glass for the purpose of protection of the solar cells 150 from external shock. In order to prevent the sun light from being reflected and to increase transmission of solar light, the front substrate 110 may be a low iron tempered glass containing low iron.

The first sealing member 131 is positioned on the light-incident surface of the solar cell 150, and the second sealing member 132 is positioned on the rear surface of the solar cell 150. The first sealing member 131 and the second sealing member 132 are attached by the lamination method. The first sealing member 131 and the second sealing member 132 can block moisture and/or oxygen that would adversely affect the solar cells 150.

As described in the above, the first sealing member 131 and the second sealing member 132 chemically combine respective elements of the solar cells 150. The first sealing member 131 and the second sealing member 132 may include ethylene-vinyl acetate copolymer resin (EVA), polyvinyl butyral, ethylene-vinyl acetate partial oxide, silicon resin, ester-based resin, and olefin-based resin.

The back sheet 120 protects the solar cells 150 at the rear surface of the solar cells 150. The back sheet 120 waterproofs, insulate, or filters ultraviolet light. The back sheet 120 may be a TPT (Tedlar/PET/Tedlar) type; but is not limited thereto. Thus, the back sheet 120 may has a PET/Al/PET type or a PVF/Al/PVF type, or various combinations of poly-ethylene-terephthalate (PET), poly ethylene naphthalate (PEN), poly vinyl butyral (PVB), poly vinyl fluoride (PVF), PNNL, and metal.

The solar cell 150 is a semiconductor device for converting solar energy to electric energy. FIG. 3 is a schematically cross-sectional view of a solar cell applicable to the solar cell modules according to embodiments of the present invention. Referring to FIG. 3, the solar cell 150 according to the present invention includes a substrate 151, an emitter layer 152, an anti-reflection layer 153, a front electrode 155, a rear electrode 157, and a back surface field layer 156.

The substrate 151 of the solar cell according to the embodiment may be a semiconductor substrate. Here, the substrate 151 is doped with a first conductive type dopant. The emitter layer 152 is formed on one surface of the substrate 151. The emitter layer 152 is doped with a second conductive type dopant opposite to the first conductive type dopant.

The anti-reflection layer 153 is formed on the emitter layer 152. In this case, one surface of the substrate 151 where the emitter layer 152 and the anti-reflection layer 153 are formed is the light-incident surface. The front electrode 155 of the solar cell 150 is formed on the anti-reflection layer 153. The front electrode 155 is electrically connected to the emitter layer 152 through penetrating the anti-reflection layer 153 by printing and heat-treating.

The rear electrode 157 is formed on the rear surface of the substrate 151. The back surface field layer 156 is formed between the rear electrode 157 and the substrate 151.

The substrate 151 may include silicon, a compound semiconductor, or a tandem structure. In the substrate 151, a P-N junction may be formed, and thus, the electric energy is generated by a photoelectric effect when the sun light is incident.

In one example of the present invention, the P-N junction may formed by forming the dopant layer on the silicon substrate. The dopant layer has a conductive type opposite to the silicon substrate.

The rear electrode 157 may be formed, for example, by printing and heat-treating a paste for the rear electrode including aluminum, quartz silica, and binder.

During a firing process, organic materials and a solvent included in the coated paste are removed. At the heat-treating, the aluminum for forming the electrode is diffused through the rear surface of the substrate 151 to form a back surface field 156 at the interface of the rear electrode layer 157 and the substrate layer 151.

Since the rear electrode 157 is entirely formed on the rear surface of the substrate 151, the back surface field layer 156 can be entirely formed on the rear surface of the substrate 151. If the back surface field layer 156 is not entirely formed, the property of the solar cell 150 can be decreases when a silver pad is formed. In the present embodiment, since the back surface field layer 156 can be entirely formed on the rear surface of the substrate 151, the decrease of the property of the solar cell 150 can be prevented.

The front surface of the substrate 151 opposite to a surface where the rear electrode 157 is formed may be a textured surface, and the front electrode 155 is formed on the front surface of the substrate 151.

A texturing is for forming a pattern of a dented-protruded shape on the surface or an uneven surface. Since the surface of the substrate 151 has a large roughness because of the textured surface, the reflectance of the incident light decreases and the substrate 151 absorbs light more. That is, the light loss can be reduced.

When the solar cell generates electricity, the solar cell generates heat due to the resistance of the solar cell. Thus, as the operation time of the solar cell increases, the temperature of the solar cell increases.

Particularly, when some solar cells are shaded by leaves or other obstacles in the solar cell module, those solar cells do not generate the electricity and are just large resistance. When a full voltage is applied to a solar cell string connected those cells, the current flows via the large resistance of the solar cells, thereby generating heat. If the temperature of the solar cell is high, filling resin of the solar cell and around the same may be discolored, and a protecting member of the rear surface may swell.

Thus, the temperature increase of the solar cell module results in the decrease of the conversion efficiency of the solar cell. If the temperature of the solar cell module increases more, the heat with a large amount is generated from the solar cells. Then, the heat may damage or destroy the solar cell module. Thus, in the present embodiment, the heat-dissipating layer is included in the solar cell module in order to suppress the above phenomenon.

The solar cell 150 may further include the ribbon 143. The ribbon 143 is adjacent to one surface of the rear electrode 157. Referring to FIGS. 1 and 2 again, the bus ribbon 145 is formed at a portion where the solar cell strings 140 are not arranged and is connected to the ribbon 143. The bus ribbon 145 may be connected to a lead line that is connected to a junction box (not shown) for charging and discharging the electric energy and for preventing countercurrent.

Also, the bus ribbon 145 alternately connects both ends of the ribbons 143 of the strings 140, thereby electrically connecting the strings 140. The bus ribbon 145 may be arranged in a row direction at the both ends of the strings 140 arranged to form the plurality of columns. The solar cell strings 140 arranged to form the plurality of columns may be positioned between the first sealing member 131 and the second sealing member 132.

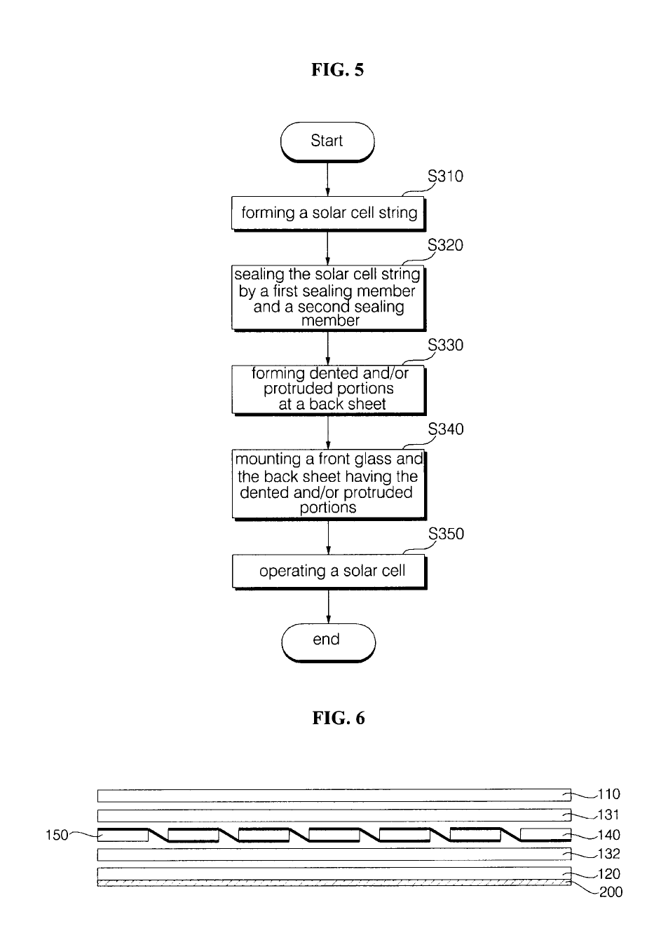

FIGS. 4, 6, and 8 are cross-sectional views illustrating solar cell modules according to embodiments of the present invention. And, FIGS. 5, 7, and 9 are flowcharts illustrating methods for manufacturing the solar cell modules according to the embodiments of the present invention.

FIG. 4 is a cross-sectional view illustrating a solar cell module including a back sheet 120 having the dented and/or protruded portions, according to an embodiment of the present invention. In addition, FIG. 5 is a flowchart illustrating a method for manufacturing a solar cell module shown in FIG. 4.

First, a solar cell string where at least two solar cells are connected is formed (S310). As described the above, the solar cells are connected by the ribbon and the bus ribbon. The first sealing member 131 and the second sealing member 132 seal the solar cell string 140 at the front and rear surface of the solar cell string 140 (S320).

Before mounting the back sheet 120, the dented and/or protruded portions are formed at the outer surface of the back sheet 120 (S330). The dented and/or protruded portions of the back sheet 120 may be formed when the back sheet 120 is formed. In more detail, the dented and/or protruded portions of the back sheet 120 may be formed by a lower substrate side of a laminator for forming the back sheet 120. That is, the dented and/or protruded portions of the back sheet 120 may be formed by a plurality of dented and/or protruded portions formed on a diaphragm for applying pressure and heat to the back sheet 120. Selectively, the dented and/or protruded portions of the back sheet 120 may be formed when the back sheet 120 is attached to the second sealing member 132. In more detail, the dented and/or protruded portions of the back sheet 120 may be formed by a plurality of dented and/or protruded portions formed on a diaphragm when the back sheet 120 is attached to the second sealing member 132. When the outer surface of the back sheet 120 includes the dented and/or protruded portions, the outer surface of the back sheet 120 has a large surface size. The heat generated from the solar cell module is conducted to the back sheet 120, and then, the heat is dissipated through the back sheet 120. Since the back sheet 120 has a large surface size by the dented and/or protruded portions, more heat is dissipated during the same amount of time. Thus, the temperature increase can be effectively suppressed. That, because the back sheet 120 has the outer surface having a large surface size, the heat-dissipation can be possible without additional heat-dissipating material.

The dented and/or protruded portions may have a circular shape or a polygonal shape. However, the dented and/or protruded portions may have various shapes so that the outer surface of the back sheet 120 has a large surface size, and thus, the embodiments are not limited thereto. The dented and/or protruded portions may be formed when the back sheet 120 is formed by the laminator. In more detail, the dented and/or protruded portions of the back sheet 120 may be formed through pressing the back sheet 120 by the laminator having dented and/or protruded portions. That is, instead of attaching separately formed dented and/or protruded portions on the back sheet 120, the dented and/or protruded portions are formed by applying heat and pressure to the back sheet 120 through the diaphragm of the laminator. The uneven surface 125 formed by the above method includes at least two dented and/or protruded portion. For example, the dented and/or protruded portions of the uneven surface have a depth of about 3 mm to about 4 mm and have a gap of about 1 cm to about 2 cm therebetween.

And, the front glass 110 is mounted on the front surface of the solar cell module, and the back sheet 120 is mounted on the rear surface of the solar cell module (S340). Thus, the front glass 110 and the back sheet 120 protect the front and rear surfaces of the solar cell. And then, the solar cell is operated (S350).

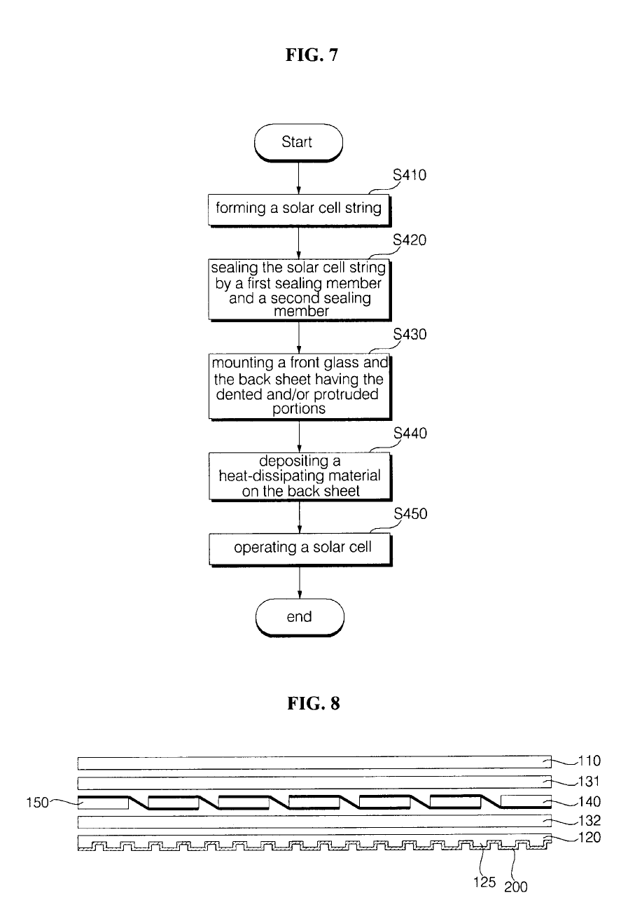

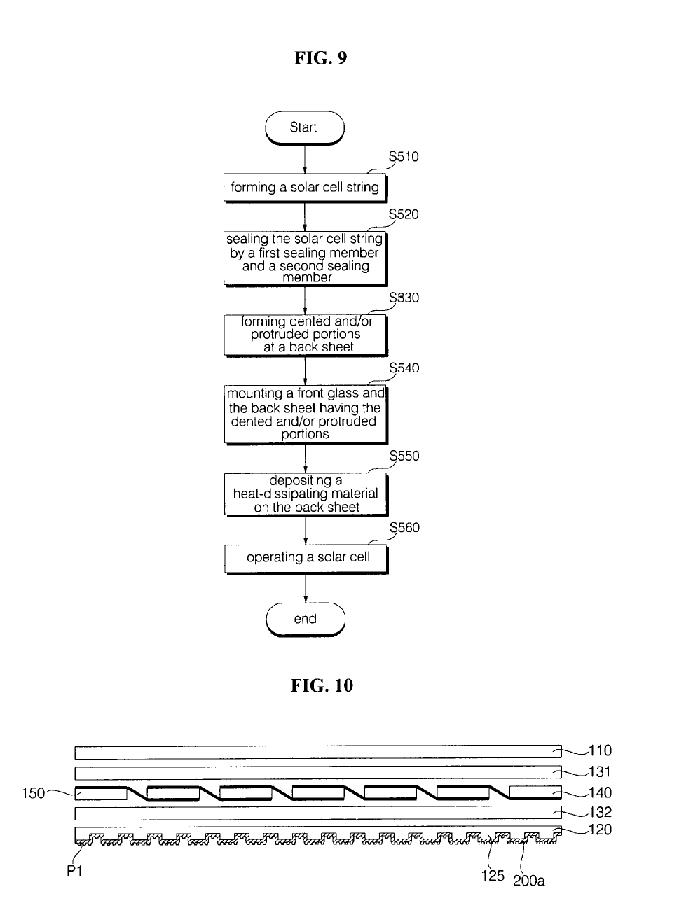

FIG. 6 is a cross-sectional view illustrating a solar cell module including a heat-dissipating layer 200, according to another embodiment of the present invention. In addition, FIG. 7 is a flowchart illustrating a method for manufacturing a solar cell module shown in FIG. 6.

First, a solar cell string 140 is formed by connecting at least two solar cells 150 (S410), and the first sealing member 131 and the second sealing member 132 seal the solar cell string 140 (S420). And then, the front glass 110 is mounted on the first sealing member 131, and the back sheet 120 is mounted on the second sealing member 132 (S430). And then, the heat-dissipating layer 200 is formed or deposited on the back sheet 120 (S440).

The material for forming the heat-dissipating layer 200 may be gel-typed heat-dissipating material such as silicon compound. Selectively, a metal having a high heat-dissipating property, or other materials may be used for the material for forming the heat-dissipating layer 200. The heat-dissipating material may be coated or be sprayed on the outer surface of the back sheet 120. The heat-dissipating layer 200 may have a thickness of about 0.1 mm to about 1 mm.

In addition, when spraying the heat-dissipating material on the outer surface of the back sheet 120 in order to form the heat-dissipating layer 200, the heat-dissipating material may be sprayed so that the heat-dissipating layer 200 can have the dented and/or protruded portions. For example, by controlling size of particles of the spayed heat-dissipating material or by temporarily inserting a mask layer during the spraying, the dented and/or protruded portions are formed at the heat-dissipating layer 200, regardless with the shape of the dented and/or protruded portions of the back sheet 120.

The dented and/or protruded portions of the heat-dissipating layer 200 have a depth of about 3 mm to about 4 mm and have a gap of about 1 cm to about 2 cm therebetween. In this case, the temperature of the solar cell module can be decreased by about 10° C., compared to the solar cell module where the heat-dissipating material is not coated.

When the heat-dissipating layer is additionally formed after mounting the back sheet 120 and the front glass 100, the heat-dissipating layer 200 can be selectively formed. Therefore, while the conventional manufacturing apparatus and process can be used, and the heat-dissipating layer 200 can be additionally formed on the solar cell module manufactured by using the conventional apparatus and/or process. Thus, the solar cell module including the heat-dissipating layer 200 can be easily manufactured.

FIG. 8 is a cross-sectional view illustrating a solar cell module including a back sheet 120 and a heat-dissipating layer 200 formed on an uneven surface 125 of the back sheet 120, according to another embodiment of the present invention. In addition, FIG. 9 is a flowchart illustrating a method for manufacturing a solar cell module shown in FIG. 8.

First, a solar cell string 140 is formed by connecting at least two solar cells 150 (S510), and the first sealing member 131 and the second sealing member 132 seal the solar cell string 140 (S520). And then, the front glass 110 is mounted on the first sealing member 131, and the back sheet 120 having the dented and/or protruded portions is mounted on the second sealing member 132 (S530, S540). Until the process that the back sheet 120 having the dented and/or protruded portions is mounted, the processes are the same as those in the descriptions referring to FIGS. 4 and 5.

In the embodiment, the heat-dissipating material is coated on the outer surface of the back sheet 120 (that is, the uneven surface 125), and thus, the heat-dissipating layer 200 is formed (S550). The heat-dissipating material may be sprayed or coated. Since the heat-dissipating layer 200 is formed on the uneven surface 125, the heat-dissipating layer 200 may have the dented and/or protruded portions with the same shape of the dented and/or protruded portions of the uneven surface 125. By depositing the heat-dissipating material with a thickness of about 1 mm or about 10 mm on the uneven surface 125, the heat-dissipating layer 200 is formed.

The heat-dissipating layer 200 has a curved shape according to the curve of the dented and/or protruded portions of the outer surface of the back sheet 120. That is, by coating the heat-dissipating material on the uneven surface of the back sheet, the heat-dissipating layer 200 has the dented and/or protruded portions according to the dented and/or protruded portions of the back sheet. Thus, the heat-dissipating layer 200 has a uneven surface same as the uneven surface of the back sheet 120. Selectively, as shown in FIGS. 10 and 11, the heat-dissipating layer 200a and 200b may include first dented and/or protruded portions formed by the dented and/or protruded portions of the back sheet 120, and second dented and/or protruded portions P1 and P2 smaller than those of the back sheet 120. That is, the heat-dissipating layer 200a and 200b includes the first dented and/or protruded portions with a relatively large size and the second dented and/or protruded portions P1 and P2 with a relatively small size. As such, the eat-dissipating layer 200a and 200b has a dented and/or protruded structure with a two-stage. In this case, as the size of the heat-dissipating layer 200a and 200b is maximized, the heat of the solar cell module is effectively dissipated, thereby reducing the temperature.

Here, as shown in FIG. 10, when the second dented and/or protruded portions P1 are regularly arranged, the heat is regularly dissipated over the heat-dissipating layer 200a. For example, the regular second dented and/or protruded portions P1 may be formed similar to the dented and/or protruded portions of the back sheet 120. That is, the regular second dented and/or protruded portions P1 may be formed through applying heat and pressure by a separating apparatus, such as diaphragm. Selectively, the regular second dented and/or protruded portions P1 may be formed by a mechanical etching method. However, the present invention is not limited thereto. The regular second dented and/or protruded portions P1 may be formed by various methods.

Here, as shown in FIG. 11, the second dented and/or protruded portions P2 may are irregularly arranged. The irregular second dented and/or protruded portions P2 may be formed by a simple method, such as a chemical etching method. The irregular second dented and/or protruded portions P2 that is not easily formed due to the small size can be easily manufactured by the simple method.

In the embodiment, the heat can be effectively dissipated by the property of the heat-dissipating material. Also, the surface size is increased by the dented and/or protruded portions, and thus, the heat from the solar cell module can be effectively more. Thus, the temperature increase can be effectively suppressed. Accordingly, when the solar cell module is operated (560), the power reduction induced by the heat form the solar cell can be reduced. As a result, the uniform output can be obtained.

According to the embodiment, the heat of the rear surface of the solar cell can be effectively dissipated, and the efficiency reduction due to the heat from the solar cell can be suppressed. In addition, because the change in the process is minimized or only tonlyhe simple process is added, the heat can be effectively dissipated. Thus, the solar cell module does not sensitively react the temperature.

Certain embodiments of the present invention have been described. However, the present invention is not limited to the specific embodiments described above; various modifications of the embodiments are possible by those skilled in the art to which the present invention belongs without leaving the scope of the present invention defined by the appended claims. Also, modifications of the embodiments should not be understood individually from the technical principles or prospects of the present invention.

What is claimed is:

1. A solar cell module, comprising:
a solar cell string including at least two solar cells for generating electricity from sun light;
a first sealing member and a second sealing member for sealing a front surface and a rear surface of the solar cell string, respectively;
a front glass positioned on the first sealing member for protecting the front surface of the solar cell module; and
a back sheet positioned on the second sealing member for protecting the rear surface of the solar cell module, wherein the back sheet including an outer surface being an even surface including at least one of a plurality of dented portions and a plurality of protruded portions.

2. The solar cell module according to claim 1, wherein the at least one of the plurality of dented portions and the plurality of protruded portions are uniformly arranged.

3. The solar cell module according to claim 1, wherein the at least one of the plurality of dented portions and the plurality of protruded portions have a circular shape or a polygonal shape.

4. The solar cell module according to claim 1, wherein the at least one of a plurality of dented portions and the plurality of protruded portions have a depth of about 3 mm to about 4 mm and have a gap of about 1 cm to about 2 cm therebetween.

5. The solar cell module according to claim 1, further comprising a heat-dissipating layer positioned on the uneven surface,
wherein the heat-dissipating layer has a thermal conductivity larger than that of the back sheet.

6. The solar cell module according to claim 5, wherein the heat-dissipating layer includes a silicon compound.

7. The solar cell module according to claim 5, wherein the heat-dissipating layer includes a first concave-protruded portion corresponding to the at least one of the plurality of dented portions and the plurality of protruded portions.

8. The solar cell module according to claim 7, wherein the heat-dissipating layer includes a second concave-protruded portion having a size smaller than that of the first concave-protruded portion.

9. The solar cell module according to claim 8, wherein the second concave-protruded portion includes a plurality of second concave-protruded portions, and
wherein the plurality of second concave-protruded portions are arranged regularly or irregularly.

10. The solar cell module according to claim 5, wherein the heat-dissipating layer has a thickness of about 0.1 mm to about 1 mm.

11. The solar cell module according to claim 5, wherein the heat-dissipating layer has a thickness smaller than a depth of the at least one of the plurality of dented portions and the plurality of protruded portions.

12. A method for manufacturing a solar cell module, comprising:
forming a solar cell string by connecting at least two solar cells for generating electricity from sun light;
forming a first sealing member and a second sealing member on a front surface and a rear surface of the solar cell string, respectively;
mounting a front glass on the first sealing member for protecting the front surface of the solar cell module; and
mounting a back sheet on the second sealing member for protecting the rear surface of the solar cell module, wherein the back sheet including an outer surface being a uneven surface including at least one of a plurality of dented portions and a plurality of protruded portions.

13. The method according to claim 12, further comprising:
forming the uneven surface of the back sheet by using a laminator including a diaphragm having at least one of a plurality of dented portions and a plurality of protruded portions, before mounting the back sheet.

14. The method according to claim 12, further comprising a heat-dissipating layer between the back sheet and the second sealing member, and
the back sheet and the heat-dissipating layer includes another at least one of a plurality of dented portions and a plurality of protruded portions to face the second sealing member.

15. The method according to claim 12, further comprising:
forming a heat-dissipating layer on the uneven surface of the back sheet.

16. The method according to claim 15, wherein the heat-dissipating layer is coated by spraying a heat-dissipating material on the uneven surface of the back sheet.

17. The method according to claim 15, wherein the heat-dissipating layer includes a first concave-protruded portion corresponding to the at least one of the plurality of dented portions and the plurality of protruded portions.

18. The method according to claim 17, wherein the heat-dissipating layer includes a second concave-protruded portion having a size smaller than that of the first concave-protruded portion.

19. The method according to claim 15, wherein, in the forming the heat-dissipating layer, the heat-dissipating layer has a thickness of about 0.1 mm to about 1 mm.

20. The method according to claim 15, wherein the at least one of a plurality of dented portions and a plurality of protruded portions have a depth of about 3 mm to about 4 mm and have a gap of about 1 cm to about 2 cm therebetween.
